(19) United States
(12) Patent Application Publication
(10) Pub. No.: US 2012/0204939 A1
(43) Pub. Date: Aug. 16, 2012

(54) Structure and Method for High Efficiency CIS/CIGS-based Tandem Photovoltaic Module

(75) Inventors: Howard W. H. Lee, Saratoga, CA (US); Robert D. Wieting, Simi Valley, CA (US)

(73) Assignee: Stion Corporation, San Jose, CA (US)

(21) Appl. No.: 13/210,345

(22) Filed: Aug. 15, 2011

Related U.S. Application Data
(60) Provisional application No. 61/376,229, filed on Aug. 23, 2010.

(51) Int. Cl. H01L 31/0725; H01L 31/18; H01L 31/042

(52) U.S. Cl. 136/249; 136/244; 438/72; 257/E31.127; 257/E31.124

(57) ABSTRACT

A tandem thin-film photovoltaic module includes a bottom device having a first PV junction including a p+ type absorber having an energy band-gap ranging from 1.0 to 1.2 eV, sandwiched between a first transparent electrode and a lower reflective electrode. The tandem module also includes a top device mechanically coupled to the bottom device. The top device is a bi-facial device having a second PV junction sandwiched by transparent conductive oxide electrodes. The second PV junction includes a second p+ type absorber engineered with an energy band-gap within 1.7 to 2.0 eV. A tandem thin-film photovoltaic module is configured have a superstrate for the top device for receiving sunlight radiation. The tandem thin-film photovoltaic module is configured to covert high-energy electromagnetic radiation to electric current at the top device and convert low-energy electromagnetic radiation to electric current at the bottom device with a combined conversion efficiency of 18% or greater.

### CROSS-REFERENCE TO RELATED APPLICATION

This application claims priority to U.S. Provisional Patent Application No. 61/376,229, filed Aug. 23, 2010, commonly assigned and incorporated by reference herein for all purposes.

### BACKGROUND OF THE INVENTION

The present invention relates generally to a thin-film photovoltaic module and manufacturing method. More particularly, the present invention provides a structure and method for manufacturing high efficiency photovoltaic module. Merely by way of example, the present invention provides multi junction CIS/CIGS-based thin-film photovoltaic tandem cells of large size and high efficiency, e.g. 165 cm×65 cm or greater with a combined conversion efficiency of 18% or greater.

Energy comes in the forms such as petrochemical, hydroelectric, nuclear, wind, biomass, solar, and more primitive forms such as wood and coal. Over the past century, modern civilization has relied upon petrochemical energy as an important energy source. Petrochemical energy includes gas and oil. Heavier forms of petrochemicals can also be used to heat homes in some places. Unfortunately, the supply of petrochemical fuel is limited and essentially fixed based upon the amount available on the planet Earth. Additionally, as more people use petroleum products in growing amounts, it is rapidly becoming a scarce resource.

More recently, environmentally clean and renewable sources of energy have been desired. An example of a clean source of energy is hydroelectric power. Hydroelectric power is derived from electric generators driven by the flow of water produced by dams. Clean and renewable sources of energy also include wind, waves, biomass, and the like. Another type of clean energy is solar energy.

Solar energy technology generally converts electromagnetic radiation from the sun to other useful forms of thermal energy and electrical energy. For electrical power applications, solar cells are often used. Although solar energy is environmentally clean and has been successful to a point, many limitations remain to be resolved before it becomes widely used throughout the world. As an example, one type of solar cell uses crystalline materials, which are derived from semiconductor material ingots. These crystalline materials can be used to fabricate optoelectronic devices that include photovoltaic and photodiode devices that convert electromagnetic radiation into electrical power. However, crystalline materials are often costly and difficult to make on a large scale. Additionally, devices made from crystalline materials often have low energy conversion efficiencies. Other types of solar cells use “thin film” technology to form a thin film of photosensitive material to be used to convert electromagnetic radiation into electrical power. Similar limitations exist with the use of thin film technology in making solar cells. Additionally, film reliability is often poor and cannot be used for extensive periods of time in conventional environmental applications. Often, thin films are difficult to mechanically integrate with each other.

From the above, it is seen that improved techniques for manufacturing photovoltaic materials and resulting devices are desired.

### BRIEF SUMMARY OF THE INVENTION

According to embodiments of the present invention, a structure and method for forming high efficiency photovoltaic module are provided. In a specific embodiment, the invention provides a thin-film photovoltaic module. The module includes a bottom device formed on a substrate having a length of about 2 feet and greater and a width of about 5 feet and greater. The bottom device includes a first electrode material formed overlying the substrate and a first photovoltaic junction having an energy band-gap of about 1 eV to 1.2 eV formed overlying the metal material. The bottom device further includes a second electrode material formed overlying the first photovoltaic junction. The thin-film photovoltaic module additionally includes a top device formed independently from the bottom device on a superstrate. The top device includes a third electrode material formed underlying the superstrate and a second photovoltaic junction with an energy band-gap of about 1.7 eV to 2.0 eV formed underlying the third electrode material. The top device further includes a fourth electrode material formed underlying the second photovoltaic junction. Furthermore, the thin-film photovoltaic module includes a coupling material configured to laminate the top device to the bottom device to form a tandem device. The tandem device converts electromagnetic energy from a sunlight spectrum to electric current with a conversion efficiency of 18% and greater.

The bottom device can be configured to be a lower circuit of the tandem device and the top device is a bi-facial top circuit of the tandem device with the superstrate as a cover. The tandem device coverts low-energy photons with a spectrum from infrared to red in solar radiation in the bottom device and covert high-energy photons with a spectrum from UV to green in solar radiation from both sides of the top device.

In another specific embodiment, the invention also provides a tandem photovoltaic module. The tandem photovoltaic module includes a top device independently formed on a second substrate having substantially the same length and width as that of the first substrate. The top device includes a second transparent electrode material formed overlying the second substrate and a second absorber material with an energy band-gap of about 1.7 eV to 2.0 eV formed overlying the second transparent electrode material. The top device further includes a second emitter material formed overlying the second absorber material and a third transparent electrode material formed overlying the second emitter material. Furthermore, the tandem photovoltaic module includes a coupling material being sandwiched between the top device and the bottom device and a cover glass disposed overlying top device. The cover glass is configured to face sunlight radiation, the top device is configured to at least convert a first partial sunlight spectrum to a first electric current and transmit a second partial sunlight spectrum and the bottom device is configured to convert the second partial sunlight spectrum to a second electric current with a combined conversion efficiency of 18% and greater.

In an alternative embodiment, the present invention provides a method for manufacturing a high efficiency thin-film photovoltaic module. The method includes supplying a first substrate having a dimension of a length of about 2 feet and greater and a width of about 5 feet and greater and a second substrate having a substantially the same dimension and shape. The method further includes forming a bottom device on the first substrate. The bottom device includes at least a first thin-film photovoltaic absorber having an energy band-gap of about 1 eV to 1.2 eV. The bottom device has a transparent upper electrode and a reflective lower electrode and is configured to absorb electromagnetic radiation energy of less than about 2.2 eV. Additionally, the method includes forming a top device on the second substrate. The top device includes at least a second thin-film photovoltaic absorber having an energy band-gap of about 1.7 eV to 2.0 eV. The top device has a bi-facial characteristic with the second thin-film photovoltaic absorber being sandwiched by two transparent electrode layers. The top device is configured to absorb electromagnetic radiation energy greater than about 2.2 eV. Furthermore, the method includes laminating the top device to the bottom device using a coupling material between the top device and the bottom device. Moreover, the method includes coupling the top device with a cover glass to form a tandem device from the top device and the bottom device, the tandem device having a combined photovoltaic efficiency of 15% or greater.

Many benefits are achieved by ways of present invention. For example, the present invention uses a decoupled process for forming each of a top device and a bottom device before mechanically coupling them together to form a laminated thin-film photovoltaic module. Both the top and bottom device have starting substrate materials that are commercially available to form a thin film of metal or semiconductor bearing materials and suitable for high temperature annealing in a specific chemical environment. The thin film of semiconductor bearing material for either the top device or bottom device can be independently processed to form a semiconductor thin film material of desired characteristics, such as atomic stoichiometry, impurity concentration, carrier concentration, doping, energy band-gap and others. Thus the process for each device can be optimized more easily and less complex. For example, the top device includes a semiconductor photovoltaic absorber material bearing an energy band-gap preferred within 1.8 eV and 1.9 eV and the bottom device contains another semiconductor thin-film absorber material having an energy band-gap preferred within 1.0 eV and 1.2 eV. Additionally, the present structure and method use a coupling material that is at least partially optically transparent to bind the top device with the bottom device to form a module with a tandem cell structure. Therefore, when sunlight shines over the top device, photons in a partial sunlight spectrum are absorbed by the top device and converted to electric current, and at least photons of another partial sunlight spectrum can also be transmitted through the coupling material and absorbed by the bottom device and converted to electric current. Other advantages include using environmentally friendly materials that are relatively less toxic than other thin-film photovoltaic materials and high temperature tolerant transparent conductive material for adapting the improved absorber thermal process and keeping reasonable optical transparency afterwards. Depending on the embodiment, one or more of the benefits can be achieved. These and other benefits will be described in more detailed throughout the present specification and particularly below.

Merely by way of example, the present method and materials include absorber materials made of copper indium disulfide species, copper tin sulfide, iron disulfide, or others for single junction cells or multi junction cells.

### BRIEF DESCRIPTION OF THE DRAWINGS

FIG. 1 is a schematic diagram illustrating a tandem cell structure for forming a thin-film photovoltaic module;

FIG. 2 is a schematic diagram illustrating a tandem cell structure for a thin-film photovoltaic module;

FIG. 3 is a diagram illustrating a sunlight spectrum and corresponding bands captured by top device and bottom device of the tandem module;

FIG. 4 is an exemplary optical transmission diagram of a sample transparent conductive oxide electrode material;

FIG. 5 is an exemplary IV characteristic diagram illustrating record efficiency for a sample 20 cm×20 cm top device;

FIG. 6 is an exemplary IV characteristic diagram illustrating record efficiency for a sample 20 cm×20 cm bottom device;

FIG. 7 is a schematic diagram illustrating a top view of a laminated sample module in 165 cm×65 cm panel dimensions; and

FIG. 8 is a schematic diagram illustrating a production distribution of photovoltaic circuit efficiency for modules with 165 cm×65 cm panel dimension.

### DETAILED DESCRIPTION OF THE INVENTION

According to embodiments of the present invention, a structure and method for forming high efficiency photovoltaic module are provided. More particularly, the present invention provides high efficiency CIS/CIGS-based thin film photovoltaic panels having 165 cm×65 cm or greater in size and multi junction tandem cells with a combined circuit efficiency of 18% or higher. The multi junction tandem cells are made by coupling at least a top device and a bottom device, each device comprising a thin-film semiconductor absorber material made by copper indium diselenide or copper indium disulfide or those mixed with gallium and other materials having respectively optimized stoichiometry and energy bandgap. Embodiments of the present invention may be used to include other types of semiconducting thin films or multilayers comprising iron sulfide, cadmium sulfide, zinc selenide, and others, and metal oxides such as zinc oxide, iron oxide, copper oxide, and others.

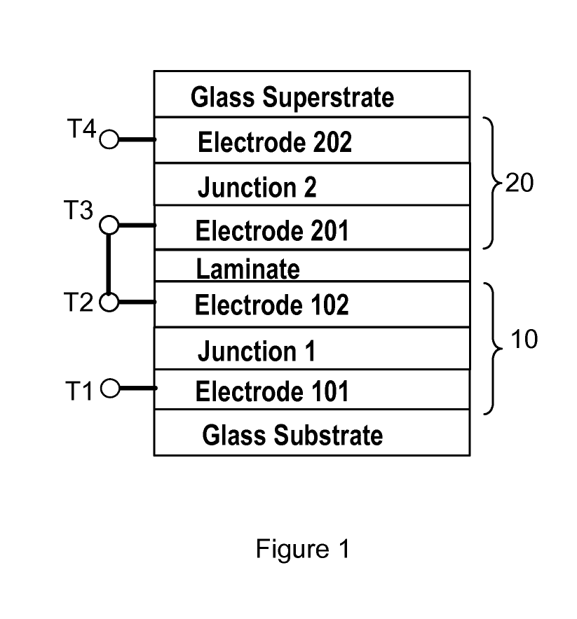

FIG. 1 is a schematic diagram illustrating a preferred tandem cell structure for forming a thin-film photovoltaic module with tandem cells according to an embodiment of the present invention. The tandem cell structure includes a lower cell 10 and an upper cell 20, which is operably coupled to the lower cell and mechanically coupled to each other via a laminate material. In a specific embodiment, the term lower and upper are not intended to be limiting. rt. In general, the upper cell, or top cell, is closer to a source of electromagnetic radiation than the lower cell or bottom cell. The upper cell receives the electromagnetic (or simply the sunlight) radiation, while the lower cell receives a partial spectrum of sunlight after traversing through the upper cell. Additionally, the top cell is a bifacial cell, which can absorb light reflected from the bottom cell and associated interfaces. Preferably the upper and lower cells are manufactured separately and then coupled to each other. In an alternative embodiment, the present invention provides a method for manufacture photovoltaic module by mechanically coupling two devices formed in decoupled processes, which leads to further simplicity in process steps and easy process optimization for large scale manufacturing, and the like.

In another embodiment, each cell in FIG. 1 is configured to form all thin-film materials on a substrate. The cell structure basically includes a photovoltaic junction sandwiched by two electrode materials. The bottom cell includes a junction 1 between electrode 101 and 102, while the top cell includes a junction 2 between electrode 201 and 202. In an embodiment, the lower electrode 101 can be made of a reflective material overlying the substrate. In a specific embodiment, the lower electrode layer can be an aluminum material, gold material, silver material, molybdenum, combinations thereof, and others. The other electrodes, 102, 201, 202 can be made of optical transparent or partial transparent material. Typically, transparent conductive material such as transparent conductive oxide (TCO) is used. The substrate can be an optically transparent solid material, though in some embodiments non-transparent material is also used. For example, the substrate can be a glass, quartz, fused silica, or a plastic, or metal, or foil, or semiconductor, or other composite materials. In an implementation, a low cost window (soda lime) glass is used. In another embodiment, the top cell in FIG. 1 can be associated with a glass superstrate based on which all thin-film materials are formed. The glass superstrate, in its plain meaning, is disposed on top of the module as a cover glass to face the sunlight or any other environmental materials. In general tempered glass is used for the glass superstrate of the top device.

In a specific embodiment, the tandem photovoltaic module includes four terminals T1 through T4. Alternatively, the tandem photovoltaic module can also include three terminals, one of which shares a common electrode proximate to an interface region between the upper cell and the lower cell. In other embodiments, the multi junction cell can also include two terminals, among others, depending upon the application. When forming a tandem cell structure, the two terminals of the top cell can be coupled to two terminals of the bottom cell electrically in series or in parallel depending on applications. Examples of other cell configurations are provided in U.S. patent application Ser. No. 12/512,978, titled “Multi junction Solar Module and Method for Current Matching Between a Plurality of First Photovoltaic Devices and Second Photovoltaic Devices,” filed on Jul. 30, 2009, commonly assigned and hereby incorporated by reference herein.

In a specific embodiment, junction 1 overlying the lower electrode layer in the bottom cell includes a thin-film semiconductor absorber material and an emitter material overlying the absorber material. In a preferred embodiment, the thin-film semiconductor absorber material is made of a copper indium diselenide, or copper indium gallium diselenide (CIGS), but can be others like Cu₂SnS₃, and FeS₂ or other metal elements, or a copper indium gallium sulfur selenide (CIGSS), depending upon the embodiment. In a specific embodiment, the absorber material is mixed by several elemental materials in a properly stoichimetric ratio and certain specific doping levels and properly thermal treated to have a desired energy band-gap in a range of Eg=1.0 to 1.2 eV. In a specific embodiment, emitter material, which is also called window layer, is formed overlying the absorber layer after the treatment process of the absorber layer. Additionally, the electrode 102 includes a transparent conductive oxide layer formed overlying the window layer. In a specific embodiment, the window layer can be a cadmium sulfide or other suitable material. In a preferred embodiment, the window layer of the lower cell is an n-type cadmium sulfide and electrode 102 is a transparent conductive oxide comprising zinc oxide or zinc oxide doped with aluminum, but can be others.

In an alternative embodiment, the top cell in FIG. 1 is associated with a glass superstrate which also acts as a cover glass for the module with tandem cells. The glass superstrate uses a tempered glass in general. Based on the superstrate, a photovoltaic junction (junction 2) is sandwiched between two electrode materials, electrode 202 and electrode 201. In a preferred embodiment, the junction 2 includes a thin-film semiconductor absorber material and an emitter material overlying the absorber material. The emitter material is an n-type semiconductor material coupled to electrode 202 which is underlying the superstrate. The thin-film semiconductor absorber material is overlying electrode 201. In a preferred embodiment, the thin-film semiconductor absorber material is a p type semiconductor layer having an energy band-gap in a range of Eg=1.7 to 2.0 eV. In a preferred embodiment, the band-gap is between 1.8 eV and 1.9 eV. In a specific embodiment, the upper p-type absorber layer is selected from CuInS₂, Cu(In,Al)S₂, Cu(In,Ga)S₂, or other suitable materials. The absorber layer is made using suitable techniques, such as those described in U.S. Ser. No. 61/059,253 filed Jun. 5, 2008, commonly assigned, and hereby incorporated by reference here.

In a specific embodiment, both electrode 201 and electrode 202 are made by transparent conductive oxide (TCO) material. In a specific embodiment, the TCO layer can be a material such as In₂O₃:Sn (ITO), ZnO:Al (AZO), SnO₂:F (TFO), but can be others. In another specific embodiment, electrode 201 can be a p+ type transparent conductive layer which is in a nearest position to couple with lower cell. In a preferred embodiment, the p+ type transparent conductive layer has an excellent electric conductivity characterized by a sheet resistance of less than or equal to about 10 Ohms/square centimeters. In addition, the p+ type transparent conductive layer also has a desired optical transmission property capable of transmitting electromagnetic radiation at least in a wavelength range from about 700 to about 630 nanometers (red, infrared) and filtering electromagnetic radiation in a wavelength range from about 490 to about 450 nanometers (green, blue, UV). For example, electrode 202 uses a TCO material that is configured to be temperature tolerant at least up to 600 degrees Celsius.

In a preferred embodiment, the tandem cell structure includes a laminate material to bind the upper cell to lower cell. The laminate material firstly is an optical coupling material that is at least partial transparency for sunlight and capable of forming strong bounding between two layers of materials. Secondly, it should be a dielectric having good electric insulation property. The laminate material can be an ethylene vinyl acetate, commonly called EVA, poly vinyl acetate, commonly called PVA, and others. In a specific embodiment, the laminate material binds electrode 102 with electrode 201 in the tandem cell structure. In an alternative embodiment, electrode 201 is formed overlying an intermediate glass substrate and the laminate material binds the electrode 102 to an underside of the intermediate glass substrate.

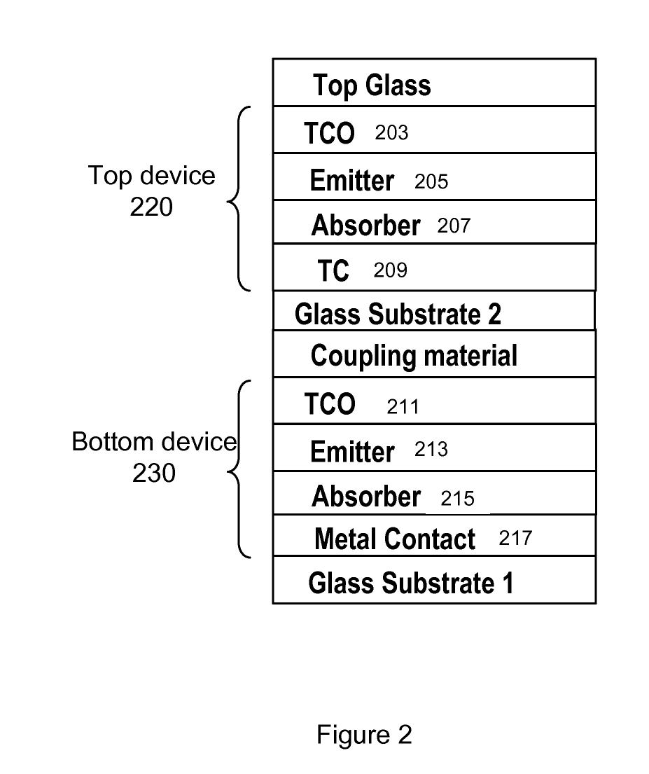

FIG. 2 is a schematic diagram illustrating a tandem cell structure for a thin-film photovoltaic module according to an embodiment of the present invention. As shown, the present invention provides a multi junction tandem photovoltaic module 200. The module includes a bottom device 230 and a top device 220. The bottom device 230 is built on top of a glass substrate 1. The top device 220 is independently built on top of a glass substrate 2 and then is operably coupled to the bottom device 230 mechanically via a coupling material to a bottom face of the glass substrate 2.

In a specific embodiment, the bottom device 230 uses a glass substrate 1 made by materials selected from, e.g., transparent glass, soda lime glass, and other optically transparent substrate or other substrate which may not be transparent. The glass material can also be replaced by other materials such as a polymer material, a metal material, or a semiconductor material, or any combinations of them. Additionally, the substrate can be rigid, flexible, or any shape and/or form depending upon the embodiment. In one or more embodiments, the glass substrate 1 can have a dimension of 5 cm×5 cm, 20 cm×20 cm, or as large as 65 cm×165 cm, or greater.

In a specific embodiment, the bottom device 230 includes a lower electrode layer 217 made of conductor material forming an electric contact. It also bears an optical property as a reflective material overlying the glass substrate 1. The lower electrode layer 217 can be a single homogeneous material, composite, or layered structure according to a specific embodiment. In a specific embodiment, the lower electrode layer 217 is made of a material selected from aluminum, silver, gold, molybdenum, copper, other metals, and/or conductive dielectric film(s), and others. The lower electrode layer reflects electromagnetic radiation that traversed through the one or more cells back to the one or more cells for producing electric current via the one or more cells.

As shown further, the bottom device 230 includes a lower absorber layer 215 overlying the lower electrode layer 217. In a specific embodiment, the absorber layer 215 is made of a thin-film semiconductor material having an energy band-gap in a range of Eg=1.0 to 1.2 eV. In a specific embodiment, the lower absorber layer 215 is made of the semiconductor material selected from Cu₂SnS₃, FeS₂, and CuInSe₂. The lower absorber layer 215 comprises a thickness ranging from about a first determined amount to a second determined amount, but can be others. Depending upon the embodiment, the photovoltaic absorber of the bottom device 230 can be formed using copper indium selenide (CIS) compound material, or copper indium gallium selenide (CIGS) compound material, or copper indium gallium sulfur selenide (CIGSS) compound material.

In a specific embodiment, the low absorber material includes copper indium selenide (“CIS”) and copper gallium selenide, with a chemical formula of CuInₓGa₍₁₋ₓ₎Se₂, where the value of x can vary from 1 (pure copper indium selenide) to 0 (pure copper gallium selenide). In a specific embodiment, the CIS/CIGS/CIGSS-based thin-film absorber material is characterized by an energy band-gap varying with x from about 1.0 eV to about 1.7 eV, but may be others, although the energy band-gap is preferably between about 1.0 to about 1.2 eV. In a specific embodiment, the CIS/CIGS/CIGSS structures can include those described in U.S. Pat. Nos. 4,611,091 and 4,612,411, which are hereby incorporated by reference herein, as well as other structures.

In a specific embodiment, the bottom device 230 further includes a lower window layer or emitter 213 overlying the lower absorber layer 215 and a lower transparent conductive oxide layer 211 overlying the lower window layer 213. In a specific embodiment, the lower window layer 213 is made of material selected from cadmium sulfide, cadmium zinc sulfide, or other suitable materials. In other embodiments, other n-type compound semiconductor materials include, but are not limited to, n-type group II-VI compound semiconductors such as zinc selenide, cadmium selenide, but can be others. The lower transparent conductor oxide layer 211 is indium tin oxide or other suitable materials, which at least partially transmits a spectrum of sunlight (passed through one or more top devices) into the lower absorber material 215 for converting to electric current therein. In a preferred embodiment, over the lower transparent conductor oxide layer 211 an optical coupling material can be applied for coupling the top device 220. In a specific embodiment, the optical coupling material can be an ethylene vinyl acetate, commonly called EVA, poly vinyl acetate, commonly called PVA, and others.

Referring to FIG. 2 again, the top device 220 of the tandem photovoltaic module 200 is coupled to the bottom device 230 via the glass substrate 2 based on which the top device is independently formed. In a preferred embodiment, the glass substrate 2 is so-called an intermediary glass having a thickness, a lower surface, and an upper surface. The upper surface is for forming the top device 220 and the lower surface is coupled to the lower transparent conductor oxide layer 211 via the optical coupling material, such as EVA and the like. In a specific embodiment, the intermediary glass substrate material can be a low iron glass, which has a thickness of a few millimeters or less. The glass substrate 2 can have a dimension of 5 cm×5 cm, 20 cm×20 cm, or as large as 65 cm×165 cm, or greater.

As shown in FIG. 2, the top device 220 includes a transparent conductor (TC) layer 209 formed overlying the glass substrate 2. In a specific embodiment, the transparent conductor layer 209 can have a p+ type electric characteristic using materials selected from ITO, AZO, and TFO, among others. In a preferred embodiment, the p+ type transparent conductor layer is characterized by a sheet resistance of less than or equal to about 10 Ohms/square centimeters and an optical transmission of 90 percent and greater for main sunlight spectrum. In another preferred embodiment, the p+ type transparent conductor layer 209 is characterized by transmitting electromagnetic radiation in at least a wavelength range from about 700 to about 630 nanometers and filtering electromagnetic radiation in a wavelength range from about 490 to about 450 nanometers. In a specific embodiment, the p+ type transparent conductor layer 209 comprises a ZnTe species, including ZnTe crystalline material or polycrystalline material. In one or more embodiments, the p+ type transparent conductor layer 209 is doped with at least one or more species selected from Cu, Cr, Mg, O, Al, or N, combinations, among others. In a preferred embodiment, the p+ type transparent conductor layer 209 is characterized to selectively allow passage of red light and filter out blue light having a wavelength ranging from about 400 nanometers to about 450 nanometers. Also in a preferred embodiment, the p+ type transparent conductor layer 209 is characterized by an energy band-gap in a range of Eg=1.7 to 2.0 eV, or a band-gap similar to that of an upper absorber layer that overlies the p+ type transparent conductor layer 209.

In a specific embodiment, the top device 220 has an upper p-type absorber layer 207 overlying the p+ type transparent conductor layer 209. In a preferred embodiment, the p-type absorber layer is made of a thin-film semiconductor material with an energy band-gap in a range of Eg=1.7 to 2.0 eV, but can be others. In an preferred embodiment, the band-gap is between 1.8 eV and 1.9 eV. In a specific embodiment, the upper p-type absorber layer can be selected from CuInS₂, Cu(In,Al)S₂, Cu(In,Ga)S₂, or other suitable metal compound materials. Similar to a formation of the lower absorber layer 215, the upper absorber layer 207 is independently processed using suitable techniques, such as those described in U.S. Ser. No. 61/059,253 filed Jun. 5, 2008, commonly assigned, and hereby incorporated by reference here.

Referring back to FIG. 2, the top device 220 further includes an upper n-type window layer 205 overlying the upper p-type absorber layer 207. In a specific embodiment, the n-type window layer is an emitter material selected from a cadmium sulfide (CdS), a zinc sulfide (ZnS), zinc selenium (ZnSe), zinc oxide (ZnO), zinc magnesium oxide (ZnMgO), or others and may be doped with impurities for characteristic electric conductivity, e.g., n⁺ type. The top device 220 also has an upper transparent conductive oxide layer 203 overlying the upper n-type window layer according to a specific embodiment. The transparent conductive oxide (TCO) layer 203 can be made by indium tin oxide and other suitable materials. For example, the TCO material can be selected from a group consisting of In₂O₃:Sn (ITO), ZnO:Al (AZO), SnO₂:F (TFO), and can be others.

In a specific embodiment, the tandem photovoltaic module also includes a top glass to cap over the upper transparent conductive oxide layer 203 of the top device 220. The top glass provides suitable support for mechanical impact and rigidity. The top glass can be optically transparent for receiving sunlight. In a specific embodiment, the top glass is mechanically coupled to the top device 220 via a coupling material. In a preferred embodiment, the coupling material can be EVA, but can be other materials.

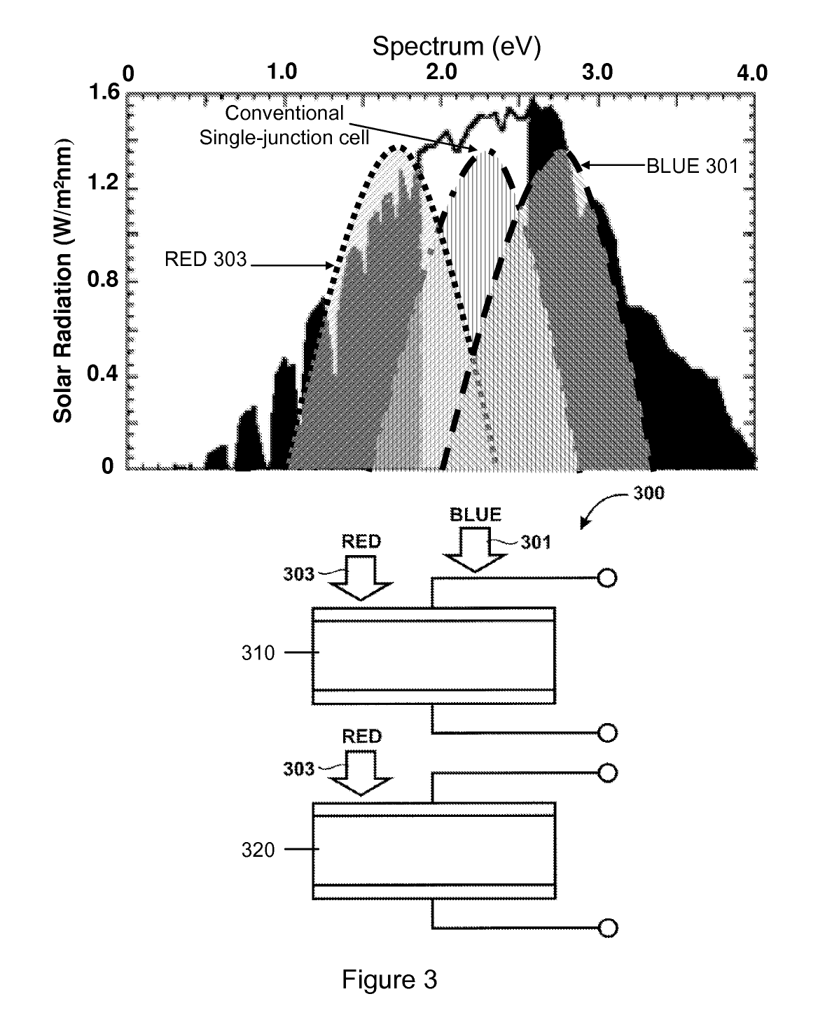

FIG. 3 is a diagram illustrating a sunlight spectrum and corresponding bands captured by top device and bottom device of multi junction tandem module according to an embodiment of the present invention. As shown, top half of the diagram provides a plot of a whole spectrum of sunlight radiation intensity that is supposed to be utilized by photovoltaic module to convert to electric current. In terms of photon energy, the band ranges from below 1 eV to above 3.5 eV. However, conventional single junction photovoltaic cell can capture only the middle portion the spectrum with a limited range from about 1.8 eV to about 2.7 eV. Partly the limit is resulted from photovoltaic absorber material itself and partly is due to the deficiency of the cell design. According to one or more embodiments of the present invention, the module 300 with multi-junction tandem cell structure includes at least a top device 310 coupled to a bottom device 320.

The top device 310 includes a first specific thin-film absorber material having a desired energy band-gap ranging from about 1.6 to 1.9 eV or wider and sandwiched by transparent conductor oxide electrodes with similar energy band-gap and proper optical transmittance and electric conductivity. This top device 310 has a first photovoltaic junction based on the first absorber (plus an emitter) preferably absorbing a “Blue” band 301 of the sunlight spectrum while filtering out a “Red” band 303 of the sunlight spectrum. The filtered red band 303 is mostly allowed to transverse through the top device 310. Additionally, the coupled bottom device 320 is configured to include a second thin-film photovoltaic absorber having a desired energy band-gap ranging from about 0.7 to 1.2 eV and also a transparent window layer overlying the absorber and a transparent electrode layer overlying the window layer. The bottom device 320 provides another photovoltaic junction based on the second absorber and emitter to capture the red band light and convert to electric current. Each device, 310 or 320, has two terminals for outputting electric current. Depending on application, the module can be configured to a 4-terminal one, 3-terminal one, or a 2-terminal one for enhancing the overall conversion efficiency of the module. Thus, multi junction module with the tandem cell structure according to embodiments of the invention is able to capture a broader range of light, providing a method for forming photovoltaic module with substantially high conversion efficiency.

According to one or more embodiments, the present invention provides a method for manufacturing high efficiency thin-film photovoltaic module using tandem cell structure. In particular, two or more cells can be coupled to each other and configured to capture broader range of light spectrum to convert into electric current. Additionally, embodiments includes form top device and bottom device independently so that each device has a simpler process steps which can be optimized much easier to achieve high conversion efficiency by itself. Either the top device or the bottom device has substantially similar processes except some choices of materials and process conditions so that manufacturing equipments and bill of materials can be simplified to substantially reduce costs. More details regarding the manufacturing method for forming either the top device or the bottom device with considerations on energy band-gap, atomic stoichiometry, impurity concentration, carrier concentration, and doping, etc. can be found in U.S. patent application Ser. No. 12/562,086 titled “Method and Structure for Thin Film Tandem Photovoltaic Cell” by inventor Howard W. H. Lee, commonly assigned to Stion Corporation and fully incorporated as a reference for all purposes.

In a specific embodiment, FIG. 2 also illustrates a method for manufacturing a high efficiency thin-film photovoltaic module with tandem cell structure. The method includes supplying a first substrate having a dimension of a length of about 2 feet and greater times a width of about 5 feet and greater and a second substrate having a substantially the same dimension and shape. Additionally, the method includes forming a bottom device on the first substrate. The bottom device includes at least a first thin-film photovoltaic absorber having an energy band-gap of about 1 eV to 1.2 eV. The first thin-film photovoltaic absorber can be formed using a two-step process by sputtering a film of a combination of materials with pre-selected stoichiometry and thermally treating the film in a pre-selected chemical environment and programmed temperature profile from 400° C. up to about 600° C. The method further includes formation of a window emitter layer overlying the formed first absorber and formation of lower or upper electrode materials as electrical contacts of the cell. Furthermore, the method includes forming a top device on the second substrate. The top device includes at least a second thin-film photovoltaic absorber having an energy band-gap of about 1.7 eV to 1.9 eV. The second thin-film photovoltaic absorber can be formed using a similar process as that for the first absorber, except that some film materials or doping materials are replaced by others for achieving its characteristic optical/electrical properties desired for the tandem cell. The method further includes laminating the top device to the bottom device via a coupling material which has been preselected to have desired optical transparency property and electrical insulation property. Moreover, the method includes capping the top device with a cover glass and adding seal material around edges and certain regions of coupling interface between the top device and bottom device. In a specific embodiment, the second substrate is transparent and configured to allow at least partial spectrum of sunlight irradiated onto the cover glass being transmitted through the coupling material to the bottom device and absorbed by the first thin-film photovoltaic absorber. In an specific tandem structured photovoltaic module, the top device is configured to absorb mainly high-energy photons in green or blue or UV light spectrum while allow red or infrared light spectrum to pass through and the bottom device is configured to absorb the red or infrared light spectrum so that the a broader sunlight spectrum is utilized for converting to electric current. The tandem structured photovoltaic module with the top device coupled to the bottom device can have a combined photovoltaic efficiency of 18% or greater.

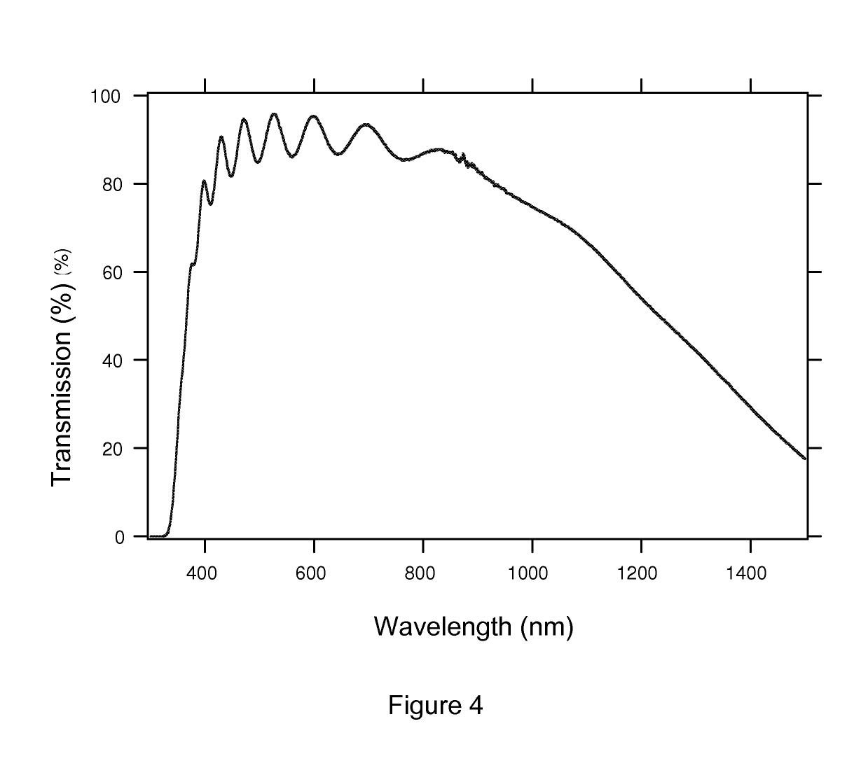

In another specific embodiment, the tandem cell structure includes utilizing one or more types of transparent conductor oxide (TCO) materials for forming either lower of upper electrode for each of the top device and bottom device. In an aspect of the TCO based electrode, optical transparency characteristic is an element of concern. FIG. 4 is an exemplary optical transmission diagram of a sample transparent conductive oxide material according to an embodiment of the present invention. As shown, the TCO has optical transmission rate of about 90% for main range of the sunlight and even has about 60% at wavelength of 1200 nm. In an embodiment, the TCO can be selected from a group consisting of In₂O₃:Sn (ITO), ZnO:Al (AZO), SnO₂:F (TFO), but can be others. In a specific embodiment, the TCO layer is patterned to maximize the efficiency of the thin film photovoltaic devices. A thickness of the electrode layer can range from about 100 nm to 2 micron, but can be others. In a specific embodiment, electrode layer is preferably characterized by a resistivity of less than about 10 Ohm/cm² according to a specific embodiment. The method of forming the TCO layer can use many techniques including Metal-organic Chemical Vapor Deposition or Chemical Bath Deposition. The TCO layer formed using these methods can have a sheet resistance of only about 6 Ohm/cm². In addition, at least one TCO electrode is made before the processing of absorber/emitter film, so the TCO as formed should be high-temperature tolerant. In an embodiment, the TCO electrode used in top device described in FIG. 1 and FIG. 2 can tolerate of temperature up to 600 Degree Celsius without causing deficiency in its optical and electric property. Of course there can be other variations, modifications, and alternatives.

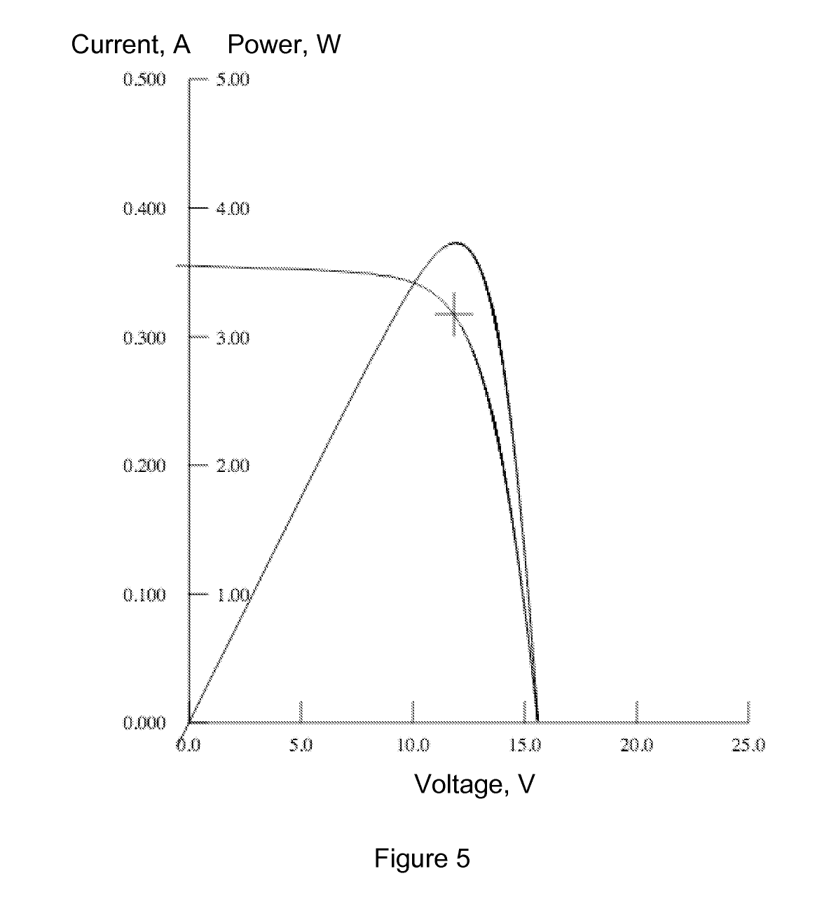

FIG. 5 is an exemplary solar cell IV characteristic diagram illustrating record efficiency measured from a sample 20 cm×20 cm top device according to an embodiment of the present invention. In this example, the top device includes a copper indium disulfide thin film photovoltaic cell. The current density of the cell is plotted against a bias voltage. Further details of the thin film photovoltaic cell and the experimental results are described in PCT Application No.: PCT/US09/46161 filed Jun. 3, 2009, commonly assigned, and hereby incorporate by reference. The curve intersects the y-axis with a short circuit current value at about 34.5 mA/cm² and intersects a zero current line with a bias at about 0.57 V. In particular, the absorber layer associated with the device is about 1.5 μm in thickness and an an energy band-gap of about 1.8 eV. Based on standard formula, a cell conversion efficiency η can be estimated:

$$η = \frac{{J}_{sc} \cdot {V}_{oc} \cdot FF}{{P}_{in} ( AM 1.5 )}$$

where J_{SC} is the short circuit current density of the cell, V_{OC} is the open circuit bias voltage applied, FF is the so-called fill factor defined as the ratio of the maximum power point divided by the open circuit voltage (Voc) and the short circuit current (J_{SC}). The fill factor for this device is 0.68. The input light irradiance (Pᵢₙ, in W/m²) under standard test conditions [i.e., STC that specifies a temperature of 25° C. and an irradiance of 1000 W/m² with an air mass 1.5 (AM1.5) spectrum.] and the surface area of the solar cell (in m²). Thus, a 13.4% efficiency can be accurately estimated for this particular device made from a method according to embodiments of the present invention.

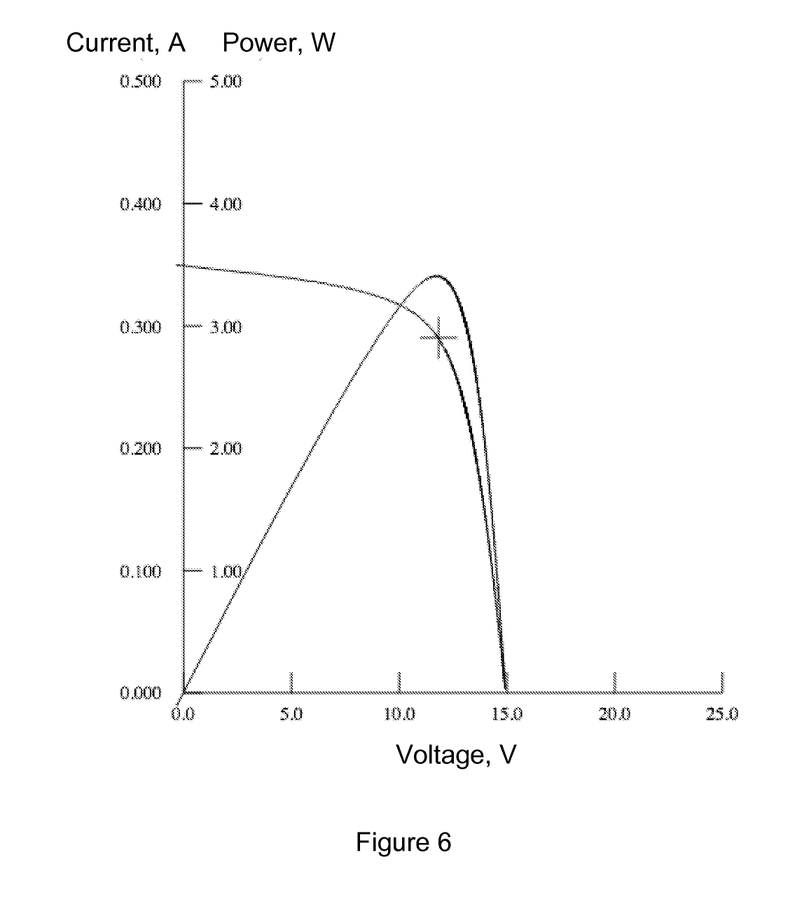

FIG. 6 is an exemplary IV characteristic diagram illustrating record efficiency measured from a sample 20 cm×20 cm bottom device according to an embodiment of the present invention. In this plot, the solar cell generated current and power are plotted against bias voltage for a bottom device manufactured according to embodiments of the present invention. As shown, the short-circuit current density J_{SC} is about 33.9 mA/cm² and the open circuit voltage is measured to be 0.55 V. The fill factor for this device is about 0.66. This yields an efficiency of about 12.3%. In this example, the absorber layer is formed by copper indium gallium diselenide material and has an energy band-gap of about 1.05 eV. Further improvements for processing the bottom device based on CIGS/CIGSS photovoltaic absorber material have led to enhancement of the device efficiency to about 15%. When the top device is coupled to a bottom device to form a tandem device, the top device facing all spectrum of sunlight with full intensity (although it is configured to mainly absorb lights from UV to green while allow the red to infrared to pass through) can be substantially performed in full efficiency described above. But the bottom device can only receive the pass-through portion of spectrum with reduced intensity, therefore, effective efficiency contribution from the bottom device would be a smaller portion of the tandem device with a combined conversion efficiency surpassing 18% or greater.

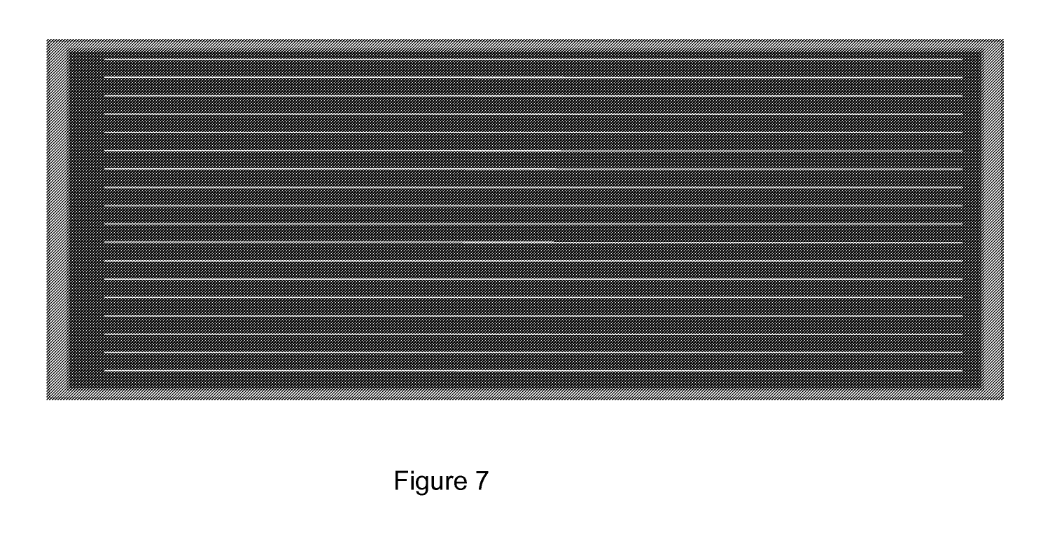

In an alternative embodiment, the method for manufacturing high efficiency photovoltaic module includes laminating the tandem module containing a top device coupled over a bottom device. FIG. 7 is a schematic diagram illustrating a top view of a laminated sample module in 165 cm×65 cm panel dimensions according to an embodiment of the present invention. As shown, the laminated module is viewed from top and through the top cover glass multiple cell line patterns can be seen. The module has a dimension of about 165 cm in length and 65 cm in width. The lamination is a fully monolithic integration of a top device mechanically stacked over the bottom device below. Thus, no process is required for stringing, tabbing, screen print, cell sorting and assembly or testing of conventional 1×1 cells. The cell line patterning has been done during the each formation step of particular layers (lower electrode layer, absorber layer, and upper electrode layer, etc.). This eliminates interconnects or solder joints used in conventional-type Si-based module during the module assembly. The dimensions and other packaging details of the panel can be easily customized for application specific PV project. For example, in the tandem photovoltaic panel, the top device can be coupled with the bottom device electrically in series so that higher cell voltage level is provided or they are coupled electrically in parallel so that the first electric current converted by the bottom device is added to the second electric current converted by the top device. All these advantages help to achieve a substantially better module reliability and a much narrower distribution in production variation for the thin-film tandem module than convention thin-film module or polysilicon cell based module.

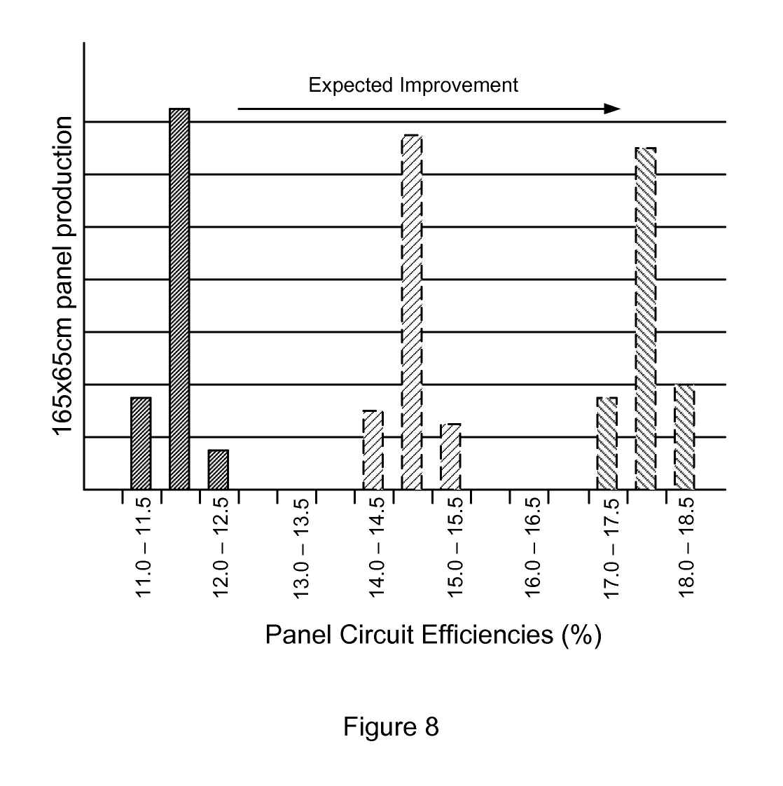

FIG. 8 is a schematic diagram illustrating a production distribution of circuit power efficiency for tandem photovoltaic modules with 165×65 cm panel dimension according to an embodiment of the present invention. As shown in FIG. 8, a circuit power efficiency histogram is plotted for productions of the tandem thin-film photovoltaic modules with a panel dimension of 165 cm×65 cm. The narrow production distribution of the efficiency histogram indicates that the manufacturing process for the thin-film modules in these panel dimensions has been very consistent with about 90% yield. Industrial standard equipments are used for processing either the top device or the bottom device with the lowest material cost (much lower than conventional crystalline silicon based module) including monolithic panel integration with high reliability. The processes have been approved to be highly scalable by applying to 5 cm×5 cm, 20 cm×20 cm, to 65 cm×165 cm module sizes. The process for each (top or bottom) device has been much simplified compared to conventional thin-film module partly due to that there are four major layers to handle for each device instead of 8-10 layers. As additional aspects of the panel processing uniformity been steadily improved step-by-step as well as further independent optimization of individual (top or bottom) device processing, the panel circuit power efficiency of the tandem modules will be improved as expected (shown in dashed histograms) following the established standard process. The power conversion efficiency of the multiple junction tandem thin-film photovoltaic modules made according to one or more embodiments of the present invention is expected to surpass 15% and even 18% or greater under AM1.5G.

Although the above has been illustrated according to specific embodiments, there can be other modifications, alternatives, and variations. It is understood that the examples and embodiments described herein are for illustrative purposes only and that various modifications or changes in light thereof will be suggested to persons skilled in the art and are to be included within the spirit and purview of this application and scope of the appended claims.

What is claimed is:

1. A thin-film photovoltaic module comprising:
a bottom device formed on a substrate having a length of about 2 feet and greater and a width of about 5 feet and greater, the bottom device comprising:
a first electrode material formed overlying the substrate;
a first photovoltaic junction having an energy band-gap of about 1 eV to 1.2 eV formed overlying the metal material; and
a second electrode material formed overlying the first photovoltaic junction;
a top device formed independently from the bottom device on a superstrate, the top device comprising:
a third electrode material formed underlying the superstrate;
a second photovoltaic junction with an energy band-gap of about 1.7 eV to 2.0 eV formed underlying the third electrode material; and
a fourth electrode material formed underlying the second photovoltaic junction; and
a coupling material configured to laminate the top device to the bottom device to form a tandem device;
wherein the tandem device converts electromagnetic energy from a sunlight spectrum to electric current with a conversion efficiency of 18% and greater.

2. The thin-film photovoltaic module of claim 1 wherein the bottom device is configured to be a lower circuit of the tandem device and the top device is a bi-facial top circuit of the tandem device with the superstrate as a cover.

3. The thin-film photovoltaic module of claim 2 wherein the tandem device is configured to covert low-energy photons with a spectrum from infrared to red in solar radiation in the bottom device and covert high-energy photons with a spectrum from UV to green in solar radiation from both sides of the top device.

4. The thin-film photovoltaic module of claim 1 wherein the first electrode material can be an aluminum material, gold material, silver material, molybdenum, combinations thereof and a transparent conductor oxide.

5. The thin-film photovoltaic module of claim 1 wherein the first photovoltaic junction comprises a first absorber material made of a chalcopyrite compound semiconductor material including a copper indium disulfide material or a copper indium diselenide material or a copper indium gallium disulfide material or a copper indium gallium diselenide material.

6. The thin-film photovoltaic module of claim 5 wherein the first photovoltaic junction comprises a first emitter material overlying the first absorber material, the first emitter material being selected from a group materials consisting of a cadmium sulfide (CdS), a zinc sulfide (ZnS), zinc selinium (ZnSe), zinc oxide (ZnO), zinc magnesium oxide (ZnMgO).

7. The thin-film photovoltaic module of claim 1 wherein the second electrode material comprises a transparent conductor oxide material selected from a group consisting of In₂O₃:Sn, ZnO:Al, ZnO:B, ZnO:F, and SnO₂:F characterized by an optical transmission of 90% at least for wavelength ranging from 700 nm to 630 nm.

8. The thin-film photovoltaic module of claim 1 wherein the third electrode material comprises a p-type transparent conductor oxide material and selected from a group consisting of In₂O₃:Sn, ZnO:Al, ZnO:B, ZnO:F, and SnO₂:F, characterized by an energy band-gap of ranging from 1.7 to 2.0 eV, an optical transmission of 90% and greater in visible spectrum, and a sheet resistance of less than or equal to about 10 Ohms/square centimeters.

9. The thin-film photovoltaic module of claim 1 wherein the third electrode material comprises a TCO material that is temperature tolerant at least up to 600 degrees Celsius.

10. The thin-film photovoltaic module of claim 1 wherein the fourth electrode material comprises a p-type transparent conductor oxide material and selected from a group consisting of In₂O₃:Sn, ZnO:Al, ZnO:B, ZnO:F, and SnO₂:F, characterized by an energy band-gap of ranging from 1.7 to 2.0 eV, about 90% optical transmission in red band (at least for wavelength range of 630-750 nm) and about 90% reflectivity in blue band (at least for wavelength range of 450-500 nm), and a sheet resistance of less than or equal to about 10 Ohms/square centimeters.

11. The thin-film photovoltaic module of claim 1 wherein the second photovoltaic junction comprises a second absorber material made of a chalcopyrite compound semiconductor material including a copper indium gallium disulfide material or a copper indium gallium diselenide material or a copper silver indium gallium disulfide material.

12. The thin-film photovoltaic module of claim 11 wherein the second photovoltaic junction comprises a second emitter material overlying the second absorber material, the second emitter material comprising n⁺ type semiconductor material selected from a group consisting of a cadmium sulfide (CdS), a zinc sulfide (ZnS), zinc selinium (ZnSe), zinc oxide (ZnO), and zinc magnesium oxide (ZnMgO) formed by MOCVD or chemical bath deposition.

13. The thin-film photovoltaic module of claim 1 wherein the coupling material comprises an ethylene vinyl acetate (EVA) or poly vinyl acetate (PVA).

14. The thin-film photovoltaic module of claim 1 wherein each of the top device and the bottom device comprises a plurality of stripe shaped cell patterns aligned to the length of the superstrate or substrate.

15. The thin-film photovoltaic module of claim 1 wherein the superstrate comprises a tempered glass.

16. The thin-film photovoltaic module of claim 1 wherein each of the first photovoltaic junction and the second photovoltaic junction comprises an absorber material independently formed by a first-step of sputtering a precursor film comprising copper species, silver species, indium species, gallium species and a second-step of thermal treating the precursor film in an environment comprising gaseous selenium species or sulfur species.

17. A tandem photovoltaic module comprising:
a bottom device formed on a first substrate having a length of about 2 feet and greater and a width of about 5 feet and greater, the bottom device comprising:
a metal material formed overlying the substrate;
a first absorber material having an energy band-gap of about 1 eV to 1.2 eV formed overlying the metal material;
a first emitter material formed overlying the first absorber material; and
a first transparent electrode material formed overlying the first emitter material;
a top device independently formed on a second substrate having substantially the same length and width as that of the first substrate, the top device comprising:
a second transparent electrode material formed overlying the second substrate;
a second absorber material with an energy band-gap of about 1.7 eV to 2.0 eV formed overlying the second transparent electrode material;
a second emitter material formed overlying the second absorber material; and
a third transparent electrode material formed overlying the second emitter material;
a coupling material being sandwiched between the top device and the bottom device; and
a cover glass disposed overlying top device;
wherein the cover glass is configured to face sunlight radiation, the top device is configured to at least convert a first partial sunlight spectrum to a first electric current and transmit a second partial sunlight spectrum and the bottom device is configured to convert the second partial sunlight spectrum to a second electric current with a combined conversion efficiency of 18% and greater.

18. The tandem photovoltaic module of claim 17 wherein the second substrate is an intermediate glass for coupling the top device to the bottom device via the coupling material overlying the first transparent electrode material.

19. The tandem photovoltaic module of claim 17 wherein the first sunlight spectrum comprises high-energy photons with energy ranging from about 2.2 eV to about 3.2 eV, and the second partial sunlight spectrum comprises low-energy photons with energy ranging from about 1.2 eV to 2.2 eV.

20. The tandem photovoltaic module of claim 17 wherein the metal material can be an aluminum material, gold material, silver material, molybdenum, combinations thereof or a transparent conductor oxide for forming an electric contact with a reflective optical property in visible spectrum.

21. The tandem photovoltaic module of claim 17 wherein the first absorber material is made of a chalcopyrite compound semiconductor material selected from a copper indium disulfide material, a copper indium diselenide material, a copper indium gallium disulfide material, a copper indium gallium diselenide material, or a copper indium gallium sulfur selenide material.

22. The tandem photovoltaic module of claim 17 wherein the first emitter material is selected from a group materials consisting of a cadmium sulfide (CdS), a zinc sulfide (ZnS), zinc selinium (ZnSe), zinc oxide (ZnO), zinc magnesium oxide (ZnMgO).

23. The tandem photovoltaic module of claim 17 wherein the first transparent electrode material comprises a transparent conductor oxide material selected from a group consisting of In₂O₃:Sn, ZnO:Al, ZnO:B, ZnO:F, and SnO₂:F characterized by an optical transmission of 90% at least for wavelength ranging from 750 nm to 630 nm and a sheet resistance of less than or equal to about 10 Ohms/square centimeters.

24. The tandem photovoltaic module of claim 17 wherein the second substrate is a low iron glass having a thickness of about a few millimeters or less.

25. The tandem photovoltaic module of claim 17 wherein the second transparent electrode material comprises a p-type transparent conductor oxide material and selected from a group consisting of In₂O₃:Sn, ZnO:Al, ZnO:B, ZnO:F, and SnO₂:F, characterized by an energy band-gap of ranging from 1.7 to 2.0 eV, about 90% optical transmission in red band (for wavelength range from 630 nm to 750 nm and greater) and about 90% reflectivity in blue band (for wavelength range from 450 nm to 500 nm and greater), and a sheet resistance of less than or equal to about 10 Ohms/square centimeters.

26. The tandem photovoltaic module of claim 17 wherein the second transparent electrode material comprises a TCO material that is temperature tolerant up to at least 600 degrees Celsius.

27. The tandem photovoltaic module of claim 17 wherein the third transparent electrode material comprises a p-type transparent conductor oxide material and selected from a group consisting of In₂O₃:Sn, ZnO:Al, ZnO:B, ZnO:F, and SnO₂:F, characterized by an energy band-gap of ranging from 1.7 to 2.0 eV, an optical transmission of 90% and greater in visible spectrum, and a sheet resistance of less than or equal to about 10 Ohms/square centimeters.

28. The tandem photovoltaic module of claim 17 wherein the second absorber material comprises a p+ type chalcopyrite compound semiconductor material selected from a copper indium diselenide material, a copper indium gallium disulfide material, a copper indium gallium diselenide material, a copper silver indium gallium disulfide material, or copper indium gallium sulfur selenide material.

29. The tandem photovoltaic module of claim 17 wherein the second emitter material comprises an n⁺ type semiconductor material selected from a group consisting of a cadmium sulfide (CdS), a zinc sulfide (ZnS), zinc selinium (ZnSe), zinc oxide (ZnO), and zinc magnesium oxide (ZnMgO) formed by MOCVD or chemical bath deposition.

30. The tandem photovoltaic module of claim 17 wherein the coupling material comprises an ethylene vinyl acetate (EVA) or poly vinyl acetate (PVA).

31. The tandem photovoltaic module of claim 17 wherein each of the top device and the bottom device comprises a plurality of stripe shaped cell patterns aligned to the length of the first substrate or the second substrate.

32. The tandem photovoltaic module of claim 17 wherein the cover glass comprises a tempered glass.

33. The tandem photovoltaic module of claim 17 wherein each of the first absorber material and the second absorber material respectively associated to the bottom device and the top device is independently formed by a first-step of sputtering a thin-film precursors comprising copper species, silver species, indium species, gallium species and a second-step of thermal treating the thin-film precursors in an environment comprising gaseous selenium species or sulfur species.

34. A method for manufacturing a high efficiency thin-film photovoltaic module, the method comprising:
supplying a first substrate having a dimension of a length of about 2 feet and greater times a width of about 5 feet and greater and a second substrate having a substantially the same dimension and shape;
forming a bottom device on the first substrate, the bottom device comprising at least a first thin-film photovoltaic absorber having an energy band-gap of about 1 eV to 1.2 eV, the bottom device having a transparent upper electrode and a reflective lower electrode, the bottom device being configured to absorb electromagnetic radiation energy of less than about 2.2 eV;
forming a top device on the second substrate, the top device comprising at least a second thin-film photovoltaic absorber having an energy band-gap of about 1.7 eV to 2.0 eV, and, the top device having a bi-facial characteristic with the second thin-film photovoltaic absorber being sandwiched by two transparent electrode layers, the top device being configured to absorb electromagnetic radiation energy greater than about 2.2 eV;
laminating the top device to the bottom device using a coupling material between the top device and the bottom device; and
coupling the top device with a cover glass to form a tandem device from the top device and the bottom device, the tandem device having a combined photovoltaic efficiency of 18% or greater.
